(19) United States
(12) Patent Application Publication
(10) Pub. No.: US 2007/0224847 A1
(43) Pub. Date: Sep. 27, 2007

(54) CONNECTOR RESILIENTLY DEFORMED EASILY WITH SMALL LOAD AND METHOD OF MANUFACTURING THE SAME

(75) Inventors: Kazuhiko Umezawa, Toyko (JP); Tetsuya Hamaguchi, Tokyo (JP); Jun Suzurikawa, Tokyo (JP); Michiki Nakano, Tokyo (JP)

Correspondence Address: DICKSTEIN SHAPIRO LLP, 1177 AVENUE OF THE AMERICAS (6TH AVENUE), NEW YORK, NY, 10036-2714, US

(73) Assignee: NEC CORPORATION, Tokyo (JP)

(21) Appl. No.: 11/754,791

(22) Filed: May 29, 2007

Related U.S. Application Data
(62) Division of application No. 11/404,084, filed on Apr. 14, 2006.

(30) Foreign Application Priority Data
Apr. 14, 2005 (JP) 2005-116515

(51) Int. Cl. H01R 12/00

(52) U.S. Cl. 439/66

(57) ABSTRACT

A connector includes a support member and a plurality of electrodes. The support member is of a plate shape and has a front surface and a rear surface. Each of the electrodes pierces through the support member to have projections which project from the front surface and the rear surface, respectively. Each of the electrodes includes a component of a column shape formed of a resilient material and a metal thin film formed on a surface of the component.

This application is a Divisional of U.S. patent application Ser. No. 11/404,084, entitled CONNECTOR RESILIENTLY DEFORMED EASILY WITH SMALL LOAD AND METHOD OF MANUFACTURING THE SAME, filed Apr. 14, 2006, which is hereby incorporated by reference in its entirety.

This application claims priority to prior application JP 2005-116515, the disclosure of which is incorporated herein by reference.

### BACKGROUND OF THE INVENTION

The present invention relates to a connector suitable for connecting a semiconductor integrated circuit element, such as a microprocessor and an application specific integrated circuit (ASIC), and to a method of manufacturing the connector.

With the advancement of the semiconductor processing technology, the integration degree of the semiconductor integrated circuit element, such as the microprocessor and the ASIC, has been increasingly improved every year. Accordingly, the number of input-output terminals of the semiconductor integrated circuit element tends to be increased. In particular, to mount a semiconductor integrated circuit element having a large number of the input-output terminals on a wiring board, the Ball Grid Array (BGA) technique has been commonly used in recent years. According to the BGA technique, a semiconductor integrated circuit element is mounted on a wiring board, and the wiring board is faced by another wiring board which has input-output terminals including a plurality of solder balls. The respective solder balls are joined to corresponding pads provided on another wiring board by soldering. Currently, a frequently used pitch size between solder balls is in an approximate range of from 1 mm to 2.5 mm. If the number of the input-output terminals is increased, however, the size of the wiring board including a BGA is increased. Further, the number of the solder balls is also increased. As a result, soldering of the solder balls to the wiring board becomes difficult.

An example of this type of connecter is described in Japanese Unexamined Patent Application Publication (JP-A) No. 2001-23750. The connector will now be described with reference to FIGS. 1 and 2.

The connector includes a multilayer tube 34 of a cylindrical shape, a plurality of ring grooves 35 formed parallel to one another on a metal thin film 33 which covers a surface of the multilayer tube 34, and conductive plated layers 36 which cover respective parts of the metal thin film 33 divided by the respective ring grooves 35. The conductive plated layers 36 are interposed between a liquid crystal display 37 and a thin electronic circuit board 38. The conductive plated layers 36 are made in contact with a plurality of electrodes 37a of the liquid crystal display 37 and with a plurality of electrodes 38a of the electronic circuit board 38, respectively, and then are compressed and deformed. Thereby, the liquid crystal display 37 electrically communicates with the electronic circuit board 38.

The multilayer tube 34 has a two-layer structure, including an insulating resilient elastomer 31 of a hollow cylindrical shape, and the metal thin film 33 of a cylindrical shape formed on an outer circumferential surface of the resilient elastomer 31 by such techniques as sputtering, dry plating, wet plating, and dipping.

The thus configured connector, however, requires the resilient elastomer 31, the metal thin film 33, the ring grooves 35 formed parallel to one another on the metal thin film 33, and the conductive plated layers 36 covering the metal thin film 33, and thus has a complicated structure.

Another example of this type of connector is described in Japanese Unexamined Patent Application Publication No. 2001-176580. The connector will now be described with reference to FIGS. 3A to 3C.

As illustrated in FIG. 3A, an electronic assembly 40 includes an electronic component, such as an integrated circuit 45, which is mounted on a chip carrier 42 having a multitude of contact pads 51 arranged in a land grid array, and another electronic component, such as a printed circuit board 56, which has a surface facing the electronic component such as the integrated circuit 45 and having contact pads 55 arranged in a land grid array. The electronic assembly 40 further includes an interposer 44 which has an array of connect buttons 48 for electrically connecting the two facing contact pads 51 and 55.

The chip carrier 42 and the printed circuit board 56 are positioned, with the interposer 44 being interposed therebetween. Each of the connect buttons 48 forms an electrically connection between the corresponding contact pads 51 and 55. The connect buttons 48 are resilient and thus allow a certain degree of non-flatness of the electronic components, while maintaining a good electrical connection between the contact pads 51 and 55 which are arranged in the land grid arrays.

As illustrated in FIG. 3B, each of the contact buttons 48 includes a flexible conductive element 52 wrapped around an insulating core 49 which is compressible and extends from one end 46 of the contact button 48 to the other end 47 of the contact button 48. The core 49 can be formed by using an insulating thread or any other appropriate derivative. The conductive element 52 and the core 49 are preferably embedded in an outer shell 53.

As illustrated in FIG. 3C, an insulating layer 54 provided around the conductive layer 52 is surrounded by a shielding layer 57 which is formed by a conductive mesh or a continuous metal. Thereby, the respective contact buttons 48 can be shielded.

However, the conductive mesh or the continuous metal is not formed on an end face of the insulating layer 54. Therefore, the shielding layer 57 fails to shield the end face of the insulating layer 54.

Another example of this type of connector is described in Japanese Unexamined Patent Application Publication No. 2002-75567. The connector will now be described with reference to FIG. 4.

As illustrated in FIG. 4, an insulating plate 80 is interposed between an electronic circuit board 60 and an electronic connection member 70. A resilient holding layer 85 is molded inside the insulating plate 80, and a plurality of resilient connections 89 are embedded in the resilient holding layer 85 to be separate from one another. Each of the resilient connections 89 is bent to have a cross-section of an approximately “2” shape. Further, each of the resilient connections 89 has connecting regions, i.e., an upper end portion 87 and a lower end portion 88, which are respectively exposed from the resilient holding layer 85.

The electronic circuit board 60 is a printed board, for example, having a surface on which a plurality of flat electrodes 61 are juxtaposed. Meanwhile, the electronic connection member 70 is an LSI or a semiconductor package, for example, having a rear surface on which a plurality of flat electrodes 71 are juxtaposed. The upper end portion 87 and the lower end portion 88 of each of the resilient connections 89 are connected to the corresponding electrode 61 of the electronic circuit board 60 and to the corresponding electrode 71 of the electronic connection member 70, respectively.

To have the resilient connections 89 absorb a warpage or a swell of the components provided on opposite sides thereof with a small load, however, the resilient connections 89 need to be reduced in thickness. Reduction in thickness of the resilient connections 89, however, makes manufacturing of the resilient connections 89 difficult, and also makes assembly of the resilient connections 89 complicated.

Another example of this type of connector is described in Japanese Unexamined Patent Application Publication No. 2003-272789. The connector will now be described with reference to FIGS. 5A and 5B.

As illustrated in FIGS. 5A and 5B, a plurality of through-holes 93 are formed in a printed board 92 of a surface-mount type package socket 90 in vertical and horizontal directions of the printed board 92. Conductive rubbers 91 are fixed in the respective through-holes 93 by bonding.

However, to fix the conductive rubbers 91 in the through-holes 93, each of the through-holes 93 needs to be larger in diameter than the corresponding conductive rubber 91. Therefore, housing capacity of a space between the through-holes 93 for housing wiring patterns is decreased.

Another conventional art example of this type of connector will now be described with reference to FIGS. 6A to 6D.

An anisotropic conductive sheet 101 includes a thin sheet 102 formed of a silicone rubber, and a multitude of conductive wires 103 embedded in the sheet 102 to pierce through a front surface and a rear surface of the sheet 102 such that the conductive wires 103 do not contact one another.

The respective conductive wires 103 connect a wiring board 104 to a semiconductor integrated circuit element 105.

Further, the anisotropic conductive sheet 101 of this conventional art needs to be applied with a large load to absorb the warpage or the swell of surfaces of components which contact a front surface and a rear surface of the anisotropic conductive sheet 101.

### SUMMARY OF THE INVENTION

It is therefore an object of the present invention to provide a connector resiliently deformable with a small load, high in density, simple in structure, and advantageous in having a shielding function, and also to provide a method of manufacturing the connector.

Other objects of the present invention will become clear as the description proceeds.

According to an aspect of the present invention, there is provided a connector comprising a support member being of a plate shape and having a front surface and a rear surface and a plurality of electrodes each piercing through the support member to have projections which project from the front surface and the rear surface, respectively, each of the electrodes comprising a component of a column shape formed of a resilient material and a metal thin film formed on a surface of the component.

According to another aspect of the present invention, there is provided a method of manufacturing a connector, comprising forming a first metal thin film on a surface of a resilient member to form a metal covering member, the metal covering member including a bottom plate portion and a multitude of electrode portions standing on a surface of the bottom plate portion, covering the surface of the bottom plate portion with a film such that the multitude of electrode portions extend through the film, forming a support member on the film such that the support member and the bottom plate portion sandwich the film and that the multitude of electrode portions project from the support member, cutting to remove only the bottom plate portion from the support member, the film, and the multitude of electrode portions such that the film and cut surfaces of the multitude of electrode portions are exposed, covering the film and the cut surfaces with a second metal thin film, and removing the film.

### BRIEF DESCRIPTION OF THE DRAWING

FIG. 1 is a perspective view of a first conventional connector;

FIG. 2 is a cross-sectional view illustrating a use state of the first conventional connector;

FIG. 3A is a cross-sectional view illustrating a use state of a second conventional connector;

FIG. 3B is a perspective view illustrating an example of the conductive button of the second conventional connector, with a part of the conductive button removed;

FIG. 3C is a perspective view illustrating another example of the conductive button of the second conventional connector, with a part of the conductive button removed;

FIG. 4 is a cross-sectional view of relevant parts of a third conventional connector in a use state;

FIG. 5A is a front view of a surface-mount type package socket according to a fourth conventional art;

FIG. 5B is a cross-sectional view of the surface-mount type package socket according to the fourth conventional art;

FIG. 6A is a front view of an anisotropic conductive sheet according to another conventional art example;

FIG. 6B is a cross-sectional view of the anisotropic conductive sheet according to the other conventional art example, as viewed from a side;

FIG. 6C is a cross-sectional view of the anisotropic conductive sheet according to the other conventional art example, as viewed from a front side;

FIG. 6D is a cross-sectional view of the anisotropic conductive sheet according to the other conventional art example in a use state;

FIG. 7 is a perspective view of a connector according to a first embodiment of the present invention;

FIG. 8 is a cross-sectional view of the connector according to the first embodiment, cut along the line VIII-VIII shown in FIG. 7;

FIGS. 9 to 15B are diagrams illustrating a method of manufacturing a plate member which is an intermediate product obtained in a process of manufacturing the connector according to the first embodiment;

FIG. 16A is a perspective view of the plate member shown in FIGS. 15A and 15B, with the plate member covered by a metal film;

FIG. 16B is an enlarged cross-sectional view of the plate member cut along the line XVIb-XVIb shown in FIG. 16A;

FIG. 17A is a perspective view of the manufactured connector according to the first embodiment;

FIG. 17B is an enlarged cross-sectional view of the connector according to the first embodiment, cut along the line XVIIb-XVIIb shown in FIG. 17A;

FIG. 18 is a cross-sectional view illustrating an example of a use state of the connector according to the first embodiment;

FIG. 19 is a cross-sectional view illustrating another example of the use state of the connector according to the first embodiment; and

FIG. 20 is a front view of relevant parts of a connector according to a second embodiment of the present invention.

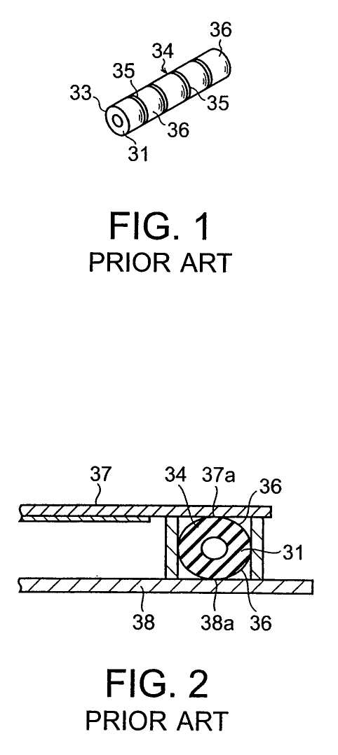

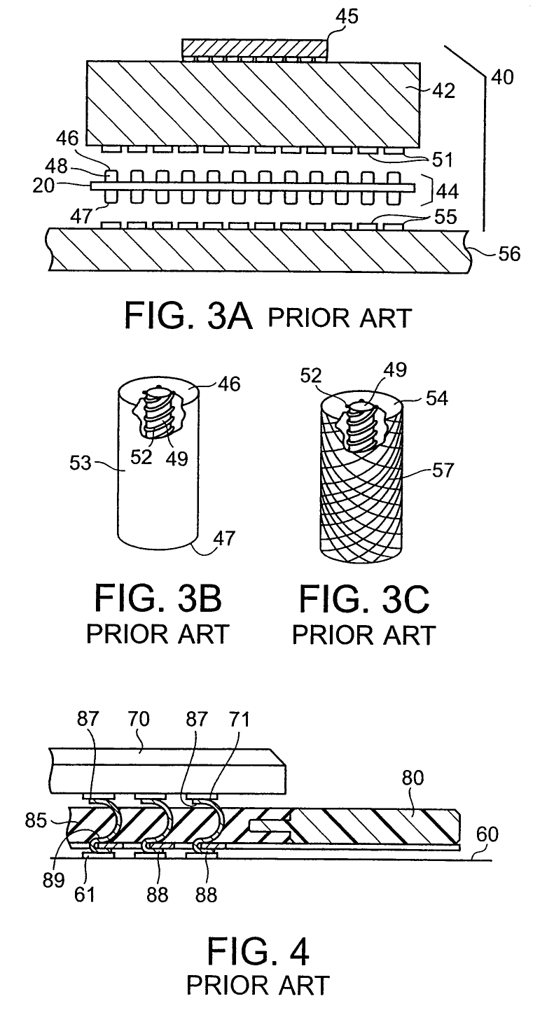

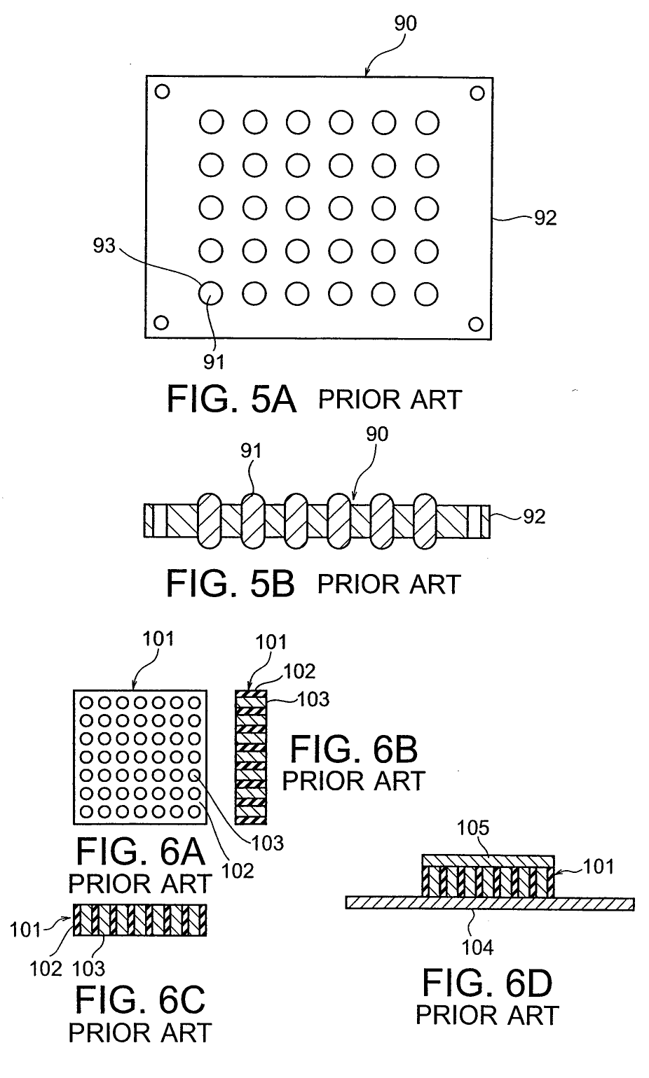

### DESCRIPTION OF THE PREFERRED EMBODIMENT

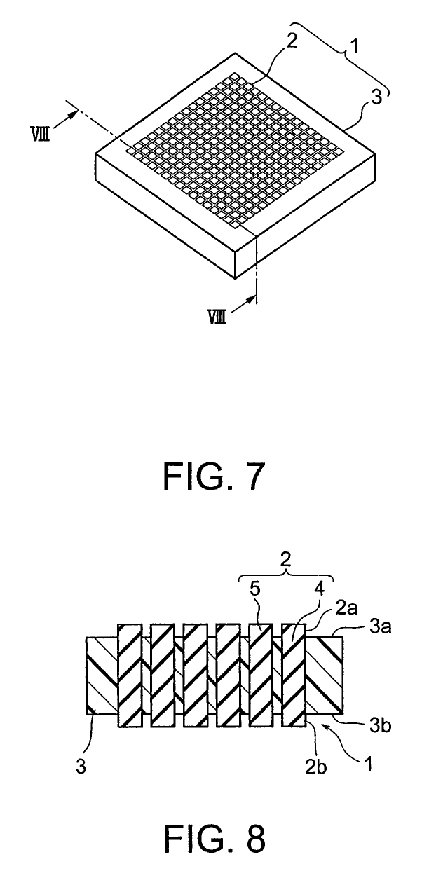

With reference to FIGS. 7 and 8, a connector according to a first embodiment of the present invention will now be described.

In FIGS. 7 and 8, a reference numeral 1 indicates the connector. In the connector 1, a multitude of electrodes 2 arrayed in a square lattice pattern are held by a support member 3 in a central region thereof. In the present example, the electrodes 2 are arrayed in the square lattice pattern. The electrodes 2, however, are not limited to any particular array. For example, the electrodes 2 may be arrayed in a houndstooth pattern or at random.

Each of the electrodes 2 includes projections 2a and 2b, which project from a front surface 3a and a rear surface 3b of the support member 3, respectively. The front surface 3a and the rear surface 3b are parallel to each other. Each of the electrodes 2 further includes a component 4 of a column shape (e.g., a cylindrical column or a rectangular column) formed of a resilient material, such as a rubber and a gel, and a metal thin film 5 formed on a surface of the component 4.

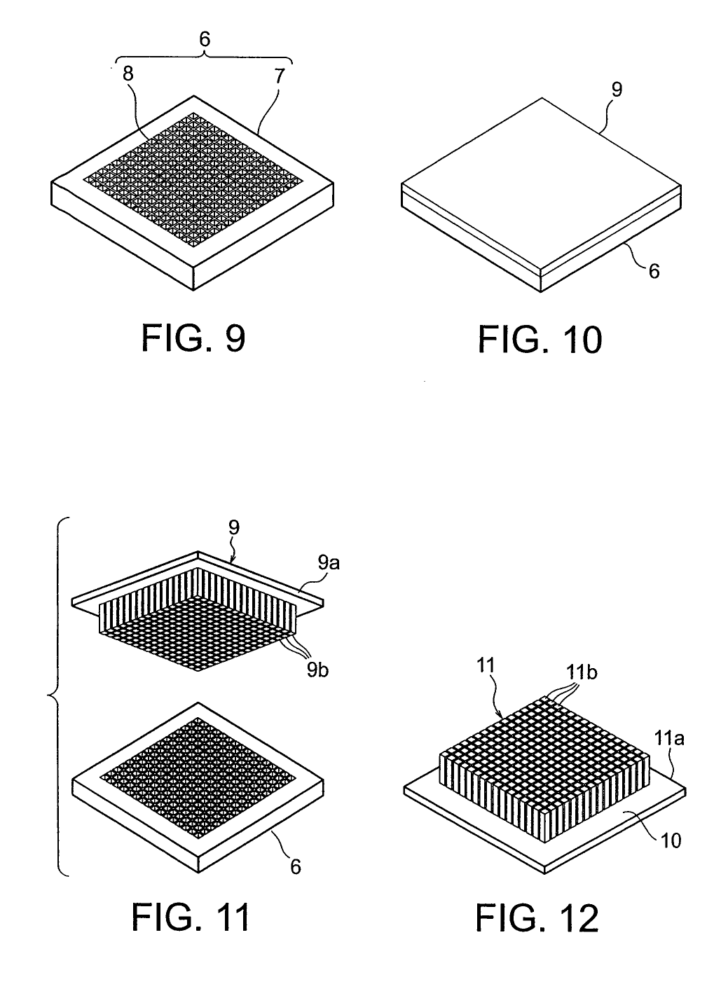

With reference to FIGS. 9 to 17B, a method of manufacturing the above-described connector will now be described.

A mold 6 shown in FIG. 9 is first prepared. The mold 6 is formed by an optical molding technique using an optical molding apparatus, as holes 8 are formed in a region of a solid material 7 corresponding to the array of the electrodes 2 such that the holes 8 pierce through a front surface and a rear surface of the solid material 7 which is of a plate shape and has a solid core. In this example, the optical molding technique is used to manufacture the mold 6. Alternatively, the holes 8 which pierce through a front surface and a rear surface of a holeless plate may be formed by using a drill or laser, for example.

Then, as a resilient material, a silicone rubber 9 in a fluid state is poured into the mold 6 to be molded. In this process, the silicone rubber 9 is flowed into the holes 8 and is also formed into a layer of a certain thickness on a surface of the mold 6. Thereby, as illustrated in FIG. 10, a composite of the mold 6 and the silicone rubber 9 is obtained. In this example, the silicone rubber is used as the resilient material. Alternatively, another type of rubber or gel may be used as the resilient material.

After the silicone rubber 9 has sufficiently hardened, as illustrated in FIG. 11, the hardened silicone rubber 9 is removed from the mold 6. In this state, the silicone rubber 9 is in such a shape that a multitude of column portions 9b stand on a surface of a plate portion 9a. The silicone rubber 9 of this shape is hereinafter referred to as a molded resilient member.

Then, as illustrated in FIG. 12, a metal thin film 10 is formed on a surface of the molded resilient member by sputtering. The metal thin film 10 covers the column portions 9b to form a connecting region at one end of each of the electrodes 2 of the connector 1. The metal thin film 10 may be formed by a method other than sputtering, such as evaporation and plating.

The molded resilient member having the surface on which the metal thin film 10 is formed is hereinafter referred to as a metal covering member 11. The metal covering member 11 is in such a shape that a multitude of electrode portions 11b stand on a surface of a bottom plate portion 11a.

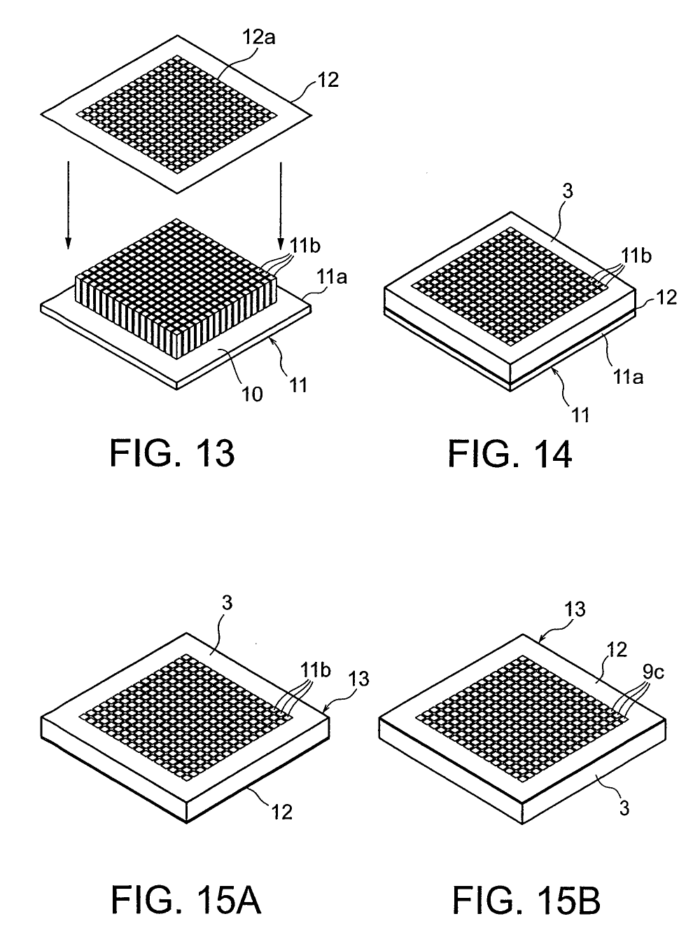

As illustrated in FIG. 13, a film 12 is prepared. The film 12 has a plurality of holes 12a which correspond one-to-one to the electrode portions 11b. Then, the film 12 is placed on the metal covering member 11 such that the respective electrode portions 11b of the metal covering member 11 are inserted through the corresponding holes 12a of the film 12 and that the film 12 is superimposed on the bottom plate portion 11a.

Then, as illustrated in FIG. 14, an ultraviolet cured resin is poured on the film 12, and the ultraviolet cured resin hardens to form the support member 3. The support member 3 penetrates into a space between the respective electrode portions lib. In this example, the ultraviolet cured resin is used to form the support member 3. Alternatively, a two-component cured resin or a thermosetting resin may be used to form the support member 3. In this state, the film 12 is sandwiched between the support member 3 and the bottom plate portion 11a of the metal covering member 11.

After the support member 3 has been formed, only the bottom plate portion 11a of the metal covering member 11 is cut and removed. Thereby, a plate member 13 as illustrated in FIG. 15A is obtained. As is observed from FIG. 15B, which illustrates the plate member 13 shown in FIG. 15A as reversed, the film 12 is adhered to a rear surface of the support member 3, while column portions of the molded resilient member are exposed as cut surfaces 9c.

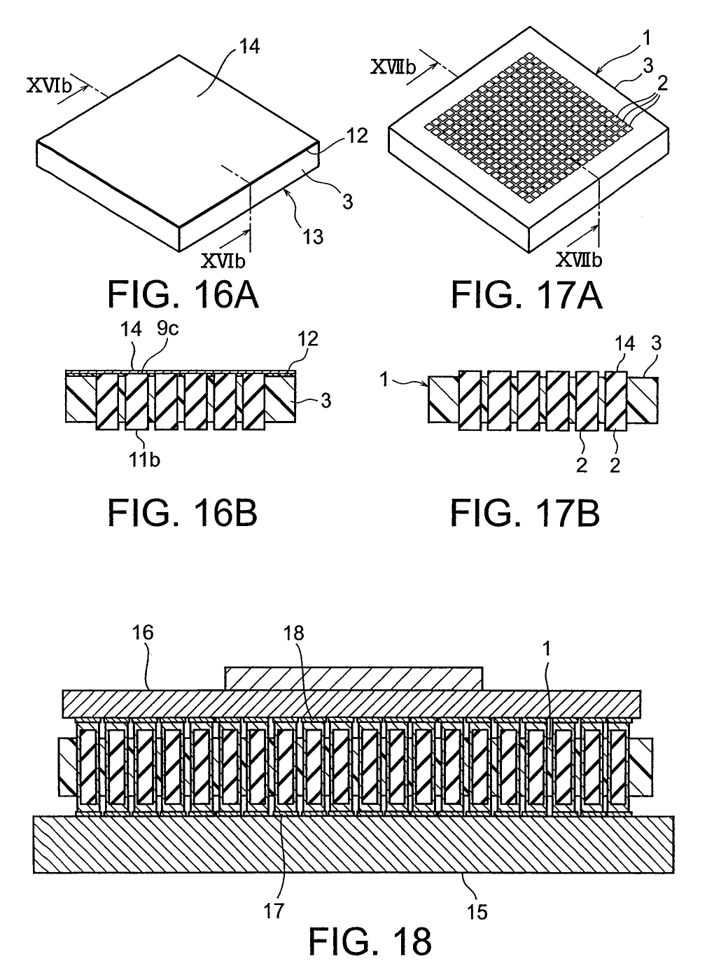

Further, as illustrated in FIGS. 16A and 16B, a metal thin film 14 is formed over the entirety of a rear surface of the plate member 13 by sputtering. As a result, the metal thin film 14 covers not only the film 12 but also the cut surfaces 9c of the column portions of the molded resilient member shown in FIG. 15B.

Finally, as illustrated in FIGS. 17A and 17B, the film 12 is peeled off and removed from the support member 3, and the connector 1 is obtained. The metal thin film 14 covering the cut surfaces 9c forms a connecting region of the other end of each of the electrodes 2 of the connector 1.

With reference to FIG. 18, a use state of the connector 1 will now be described.

In FIG. 18, the connector 1 is mounted on a wiring board 15. Further, a Land Grid Array (LGA) 16 is mounted at a side of the connector 1 opposite to a side thereof facing the wiring board 15. A plurality of pads 17 provided on the wiring board 15 are electrically connected to corresponding pads 18 provided on the LGA 16 via the electrodes 2 of the connector 1.

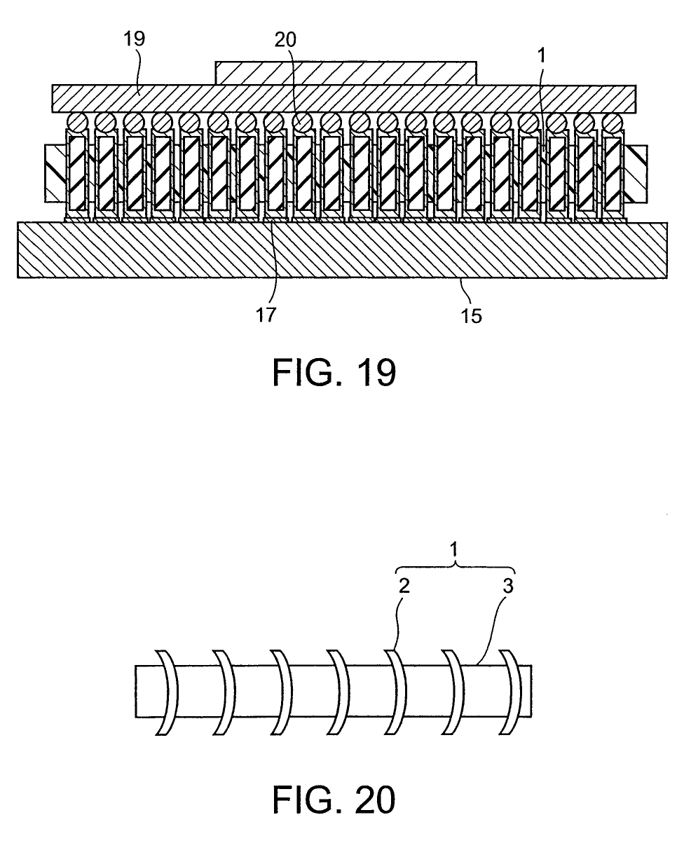

In FIG. 19, a Ball Grid Array (BGA) 19 replaces the LGA 16 shown in FIG. 18. The pads 17 provided on the wiring board 15 are electrically connected to corresponding solder balls 20 provided on the BGA 19 via the electrodes 2 of the connector 1.

In the above cases, even if flatness of a contact surface between the electrodes 2 of the connector 1 and the wiring board 15 or between the electrodes 2 of the connector 1 and the LGA 16 or the BGA 19 is not ensured due to such factors as a warpage or a swell of the wiring board 15, the LGA 16, or the BGA 19, and variation in height between the pads 17 of the wiring board 15, the pads 18 of the LGA 16, and the solder balls 20 of the BGA 19, the respective electrodes 2 are independently compressed, and thus electrical connection is ensured.

The connector 1 can be used in place of soldering to connect a semiconductor integrated circuit element, such as a microprocessor and an ASIC, to a wiring board. Further, the connecter 1 can be easily attached and detached, and thus is suitable to be used in a test apparatus of such a semiconductor integrated circuit element.

With reference to FIG. 20, a connector according to a second embodiment of the present invention will now be described.

The respective electrodes 2 of the connector 1 are bent. With the electrodes 2 thus bent, the electrodes 2 are deformed not only by simple compression but also by bending. Accordingly, the electrodes 2 can further flexibly respond to the variation in flatness of the contact surface.

While the present invention has thus far been described in connection with a few embodiments thereof, it will readily be possible for those skilled in the art to put this invention into practice in various other manners.

What is claimed is:

1. A method of manufacturing a connector, comprising:
forming a first metal thin film on a surface of a resilient member to form a metal covering member, the metal covering member including a bottom plate portion and a multitude of electrode portions standing on a surface of the bottom plate portion;
covering the surface of the bottom plate portion with a film such that the multitude of electrode portions extend through the film;
forming a support member on the film such that the support member and the bottom plate portion sandwich the film and that the multitude of electrode portions project from the support member;
cutting to remove only the bottom plate portion from the support member, the film, and the multitude of electrode portions such that the film and cut surfaces of the multitude of electrode portions are exposed;
covering the film and the cut surfaces with a second metal thin film; and
removing the film.

2. The method according to claim 1, wherein the film includes a plurality of holes through which the multitude of electrode portions are inserted.

3. The method according to claim 1, wherein the support member is formed of an ultraviolet cured resin.

4. The method according to claim 1, wherein the support member is formed of a two-component cured resin.

5. The method according to claim 1, wherein the support member is formed of a thermosetting resin.

6. The method according to claim 1, further comprising:
preparing a mold of a plate shape including a surface and a plurality of holes extending from the surface in a thickness direction of the mold;
placing a resilient material on the surface and in the holes;
hardening the resilient material to form a molded resilient member;
removing the molded resilient member from the mold; and
forming the first metal thin film on a surface of the molded resilient member to form the metal covering member.

7. The method according to claim 6, wherein the holes are formed by an optical molding technique.

8. The method according to claim 6, wherein the holes are formed by a drill.

9. The method according to claim 6, wherein the holes are formed by a laser.
